(19) United States
(12) Patent Application Publication
(10) Pub. No.: US 2011/0238341 A1
(43) Pub. Date: Sep. 29, 2011

(54) High Power DC Kilowatt Hour Meter

(76) Inventors: Mehdi Etezadi-Amoli, Reno, NV (US); Dana McPherson, Reno, NV (US)

(21) Appl. No.: 13/072,111

(22) Filed: Mar. 25, 2011

Related U.S. Application Data
(60) Provisional application No. 61/317,417, filed on Mar. 25, 2010.

(51) Int. Cl. G06F 19/00; H02J 7/00; H05K 13/00

(52) U.S. Cl. 702/61; 320/109; 29/592.1

(57) ABSTRACT

A high voltage and high current direct current (DC) power meter utilizes step down circuits and optocoupling to generate analog signals that are representative of current through a load and voltage across the load, but that are scaled appropriately for processing by analog to digital conversion circuitry. Power meters consistent with the invention in many cases may be inexpensive, small, solid state and very accurate, and adaptable for use in measuring a wide range of high voltages and currents. A high voltage and high current DC power meter, a method of assembling such a power meter, a method of calculating power consumed by a load with such a power meter, an apparatus to calculate energy consumed by a load, and a program product to calculate energy consumed by the load are provided.

### CROSS REFERENCE TO RELATED APPLICATION

This application claims the benefit of U.S. Provisional Application No. 61/317,417, filed Mar. 25, 2010, the disclosure of which is hereby incorporated by reference herein in its entirety.

### FIELD OF THE INVENTION

The invention is generally related to power meters, and in particular, power meters for measuring consumed direct current (DC) power.

### BACKGROUND OF THE INVENTION

The growing demand for electric cars also results in demand for electric recharging stations. However, for recharging stations to function owners would need a high power DC kilowatt hour meter to measure the energy consumed by their customers and generate an invoice. Unfortunately, there are none currently on the market.

There are a number of techniques currently used for DC metering. However, few techniques are designed to handle high voltage and high current. One of the techniques to measure high voltage DC signals uses a field mill, a device that measures the rate that charge collects on an initially uncharged sensor plate. That rate of collection is equivalent to the strength of the applied electric field. However, a field mill set up is not practical for a use in a recharging station. Each pump at a recharging station would require its own meter, and field mills are generally bulky and require high precision in plate separation, which is not optimal for mass production. In addition, the recharging station's meters must not only tolerate high voltages, but also high currents.

Therefore, a need continues to exist in the art for a high power DC kilowatt hour meter that measures power consumed by a customer, and optionally calculates the total cost and/or prints an invoice for the energy used.

### SUMMARY OF THE INVENTION

Embodiments of the invention address these and other problems associated with the prior art by providing a high voltage and high current direct current (DC) power meter that utilizes step down circuits and optocoupling to generate analog signals that are representative of current through a load and voltage across the load, but that are scaled appropriately for processing by analog to digital conversion circuitry. Power meters consistent with the invention in many cases may be inexpensive, small, solid state and very accurate, and adaptable for use in measuring a wide range of high voltages and currents.

Consistent with one aspect of the invention, a high voltage and high current direct current (DC) power meter is provided, which includes a current step down circuit configured to sense a current applied to a load by a power source, the current step down circuit including a shunt element coupled in series with the load and configured to generate a first analog signal having a voltage representative of current through the load; and a voltage step down circuit configured to sense a voltage across the load, the voltage step down circuit including a voltage divider coupled in parallel with the load and configured to generate a second analog signal having a voltage representative of voltage across the load. The power meter also includes a first isolation amplifier circuit including a first optocoupler and configured to generate from the first analog signal a first isolated analog signal having a voltage representative of the current through the load; a second isolation amplifier circuit including a second optocoupler and configured to generate from the second analog signal a second isolated analog signal having a voltage representative of the voltage across the load; an analog to digital conversion circuit isolated from the current and voltage step down circuits by the first and second isolation amplifier circuits and configured to respectively generate from the first and second isolated analog signals first and second digital signals respectively representative of the current through the load and the voltage across the load; and a controller coupled to the analog to digital conversion circuit and configured to calculate consumed energy for the load by calculating instantaneous power consumed by the load at a plurality of sample points using the first and second digital signals and integrating the instantaneous power over time.

Consistent with another aspect of the invention, a method of assembling a high voltage and high current DC power meter is provided. The method comprises configuring a current step down circuit that includes a shunt element adaptable to couple in series with a load and configured to generate a first analog signal having a voltage representative of a current through the load and configuring a voltage step down circuit that includes a voltage divider adaptable to couple in parallel with the load and configured to generate a second analog signal having a voltage representative of a voltage across the load. The method further comprises coupling a first isolation amplifier circuit that includes a first optocoupler to the first analog signal to generate a first isolated analog signal having a voltage representative of the current through the load and coupling a second isolation amplifier circuit that includes a second optocoupler to the second analog signal to generate a second isolated analog signal having a voltage representative of the voltage through the load.

Another aspect of the invention includes a method of calculating power consumed by a load. This method comprises coupling at least a portion of a current step down circuit in series with a load, generating a first analog signal that is representative of a current through the load with the current step down circuit, coupling at least a portion of a voltage step down circuit in parallel with the load, and generating a second analog signal that is representative of a voltage across the load with the voltage step down circuit. The method further comprises optoelectrically isolating the first analog signal to generate a first isolated analog signal, optoelectrically isolating the second analog signal to generate a second isolated analog signal, converting the first and second isolated analog signals into respective first and second digital signals, and calculating power consumed by the load based upon the first and second digital signals.

Consistent with yet other aspects of the invention, an apparatus to calculate power consumed by a load is provided. The apparatus includes at least one processing unit, a memory, and program code resident in the memory. The program code is configured to be executed by the at least one processing unit to receive a plurality of first digital signals representative of a current through a load at respective times, receive a plurality of second digital signals representative of a voltage across the load at the respective times, and calculate kilowatt hours consumed by the load based upon the respective pluralities of first and second digital signals.

Moreover, yet another aspect of the invention includes a program product. The program product includes program code configured to be executed by at least one processing unit to receive a plurality of first digital signals representative of a current through a load at respective times, receive a plurality of second digital signals representative of a voltage across the load at the respective times, and calculate kilowatt hours consumed by the load based upon the respective pluralities of first and second digital signals. The program product further includes a computer recordable medium bearing the program code.

These and other advantages and features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there is described exemplary embodiments of the invention.

### BRIEF DESCRIPTION OF THE DRAWINGS

FIG. 1 is a block diagram of an example implementation of a high power DC power meter consistent with the invention.

FIG. 2 is a circuit diagram of an exemplary implementation of a step down portion of the high power DC power meter of FIG. 1.

FIG. 3 is a circuit diagram of an exemplary test system capable of providing several variable load steps to the high power DC power meter of FIG. 1.

FIG. 4 is a flowchart illustrating exemplary steps performed by the program executed by the high power DC power meter of FIG. 1.

### DETAILED DESCRIPTION

Embodiments consistent with the invention providing a high voltage and high current direct current (DC) power meter suitable for use in electric vehicle charging stations and similar high power applications. The high voltage and high current DC power meter, which may be referred to hereinafter as a “high power” DC power meter, or more simply, a “meter,” utilizes step down circuits and optocoupling to generate analog signals that are representative of current through a load and voltage across the load, but that are scaled appropriately for processing by analog to digital conversion circuitry.

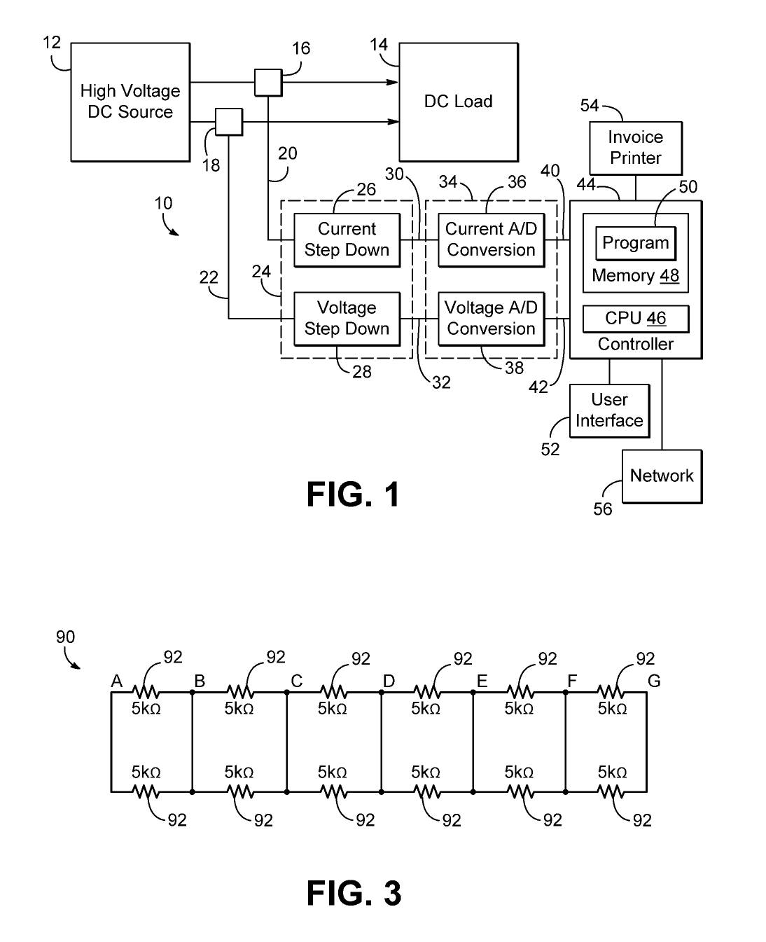

Turning now to the Drawings, wherein like numbers denote like parts throughout the several views, FIG. 1 illustrates a high power DC power meter 10 consistent with the principles of the invention. Meter 10 is configured to sense the DC power output by a high voltage DC source 12 and consumed by a DC load 14, e.g., for use in a charging station to meter the consumption of power by an electric vehicle during charging of the vehicle's batteries. However, meter 10 may have other applications so the invention is not so limited to use in a vehicle charging station.

Meter 10 includes a transducer 16 and voltmeter 18, which respectively sample the current and voltage drawn by DC load 14 from DC source 12. Signals representative of the current and voltage are respectively output by transducer 16 and voltmeter 18 over lines 20, 22 to a step down circuit 24, which includes separate current and voltage step down circuits 26, 28. Step down circuits 26, 28, in conjunction with transducer 16 and voltmeter 18, step down the signals representing current and voltage to levels suitable for analog to digital (A/D) conversion, and output stepped down signals representing current and voltage over lines 30, 32. In addition, as will be discussed in greater detail below, the stepped down signals are also isolated from the load and the power source by optocoupling to prevent ground loops and isolation. An A/D conversion circuit 34, including separate current and voltage A/D conversion circuit 36, 38, converts the analog stepped down signals representing current and voltage to digital signals, output respectively over lines 40, 42.

The digital signals representing current and voltage are then provided to a controller 44, e.g., including a CPU 46 and a memory 48, and instructions from a program 50, stored in memory 48 and executed by CPU 46, process the signals representing current and voltage to calculate an amount of power consumed by the load. This amount of power (typically measured in units of kilowatts) is also integrated over time to generate the consumed energy (typically measured in units of kilowatt hours (KWH)), and may further be used to generate a cost based upon a current rate. The data, including one or more of the cost, the rate, the power, the current, the voltage, the scan rate, the time period, etc., as well as other data derived from such data, e.g., instantaneous power/voltage/current, average power/voltage/current, peak power/voltage/current, etc., is typically stored in memory 48. In addition, such data may also be output to external devices, e.g., to a user interface (e.g., a display) 52 for display to a customer, to an invoice printer 54 for the purpose of printing an invoice, and/or to a network 56 for communication to a remote device, such as an accounting or payment system (e.g., to charge a customer's credit card or utility account for the cost of the charge).

It will be appreciated that controller 44 may be implemented using various types of computers, or may be implemented using a microcontroller or a dedicated semiconductor device, or using any other hardware-based logic suitable for implementing the functions described herein. As such, the controller 44 may be at least one computer, computer system, computing device, server, disk array, or programmable device such as a multi-user computer, a single-user computer, a handheld device, a networked device (including a computer in a cluster configuration), etc. Correspondingly, the CPU 46 of the controller 44 may be one or more processing units which are typically implemented in hardware using circuit logic disposed in one or more physical integrated circuit devices, or chips. Specifically, CPU 46 may be one or more microprocessors, micro-controllers, field programmable gate arrays, or ASICs, while memory 48 may include random access memory (RAM), dynamic random access memory (DRAM), static random access memory (SRAM), flash memory, electronically erasable programmable read-only memory (illustrated as, and hereinafter, “EEPROM”), and/or another digital storage medium, and is also typically implemented using circuit logic disposed on one or more physical integrated circuit devices, or chips. As such, memory 48 may be considered to include memory storage physically located elsewhere in the controller 44 (e.g., any cache memory in the CPU 46), as well as any storage capacity used as a virtual memory, e.g., as stored on a mass storage device locally or stored remotely on another controller coupled to the controller 44 through the network 56.

It will be appreciated that controller 44 may have other functionality for managing the overall operation of a charging station, e.g., controlling the DC source 12, interacting with a customer to receive customer information prior to initiating a charging sequence, etc. The invention is therefore not limited to the particular embodiments disclosed herein.

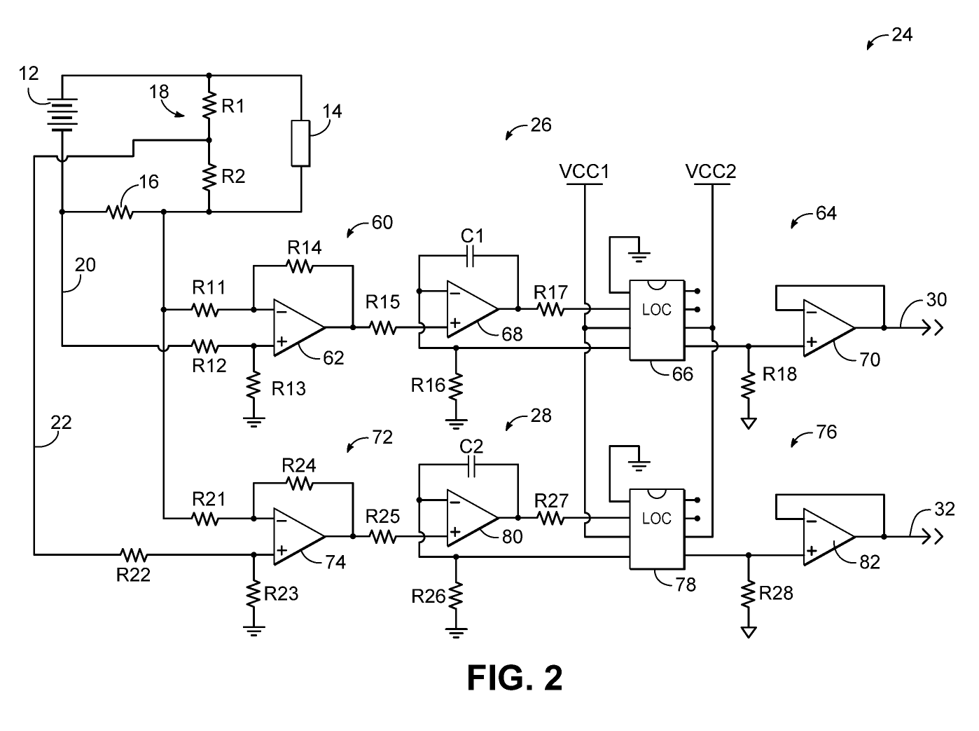

FIG. 2 next illustrates circuit logic utilized in one implementation of meter 10 consistent with embodiments of the invention. To generate the signal representing current through the load on line 20, transducer 16 is implemented using a shunt element, which can be specified to measure the load current and produce a desired voltage across its terminals. Advantageously, this feature serves two purposes. First, it reads the current signal in the form of a voltage which is easier to manipulate, and is easily converted back in controller 44. Secondly, by choosing an appropriate shunt element, the voltage reading obtained is essentially stepped down. In order to minimize losses in the circuit, it may be desirable to use a shunt with the smallest possible voltage drop. For example, a nichrome wire with a resistance of about 0.054Ω may be used in one test embodiment discussed in greater detail below, and provide a current to voltage ratio of about 20 A to 1V. In many practical high current applications (e.g., applications where the current may be about 300 A or higher), shunt elements that provide different ratios, such as 200 A to 1V, 1000 A to 1V, etc., may be used so that the voltage across the shunt is in a suitable range for further processing. The invention may also use other forms of devices to implement a shunt consistent with the invention.

By using such a small element, however, the voltage across the shunt terminals will be equally small. Therefore, in order to read the signal representing current into an ND converter, the voltage typically must be stepped up. In the embodiment of FIG. 2, an amplifier circuit 60 including an op-amp 62 and resistors R11-R15 is used, and for convenience the gain is set to produce an output voltage of about 2V, which is approximately equal to the signal representing voltage (discussed below).

In amplifier circuit 60, the positive input of op-amp 62 is coupled to the negative terminal of DC source 12 on one side of shunt 16, through resistor R12, and coupled to ground through resistor R13. The negative input of op-amp 62 is coupled to the opposite side of shunt 16 through a resistor R11, with a feedback loop coupled between the output and negative input of op-amp 62 through a feedback resistor R14. An output resistor R15 is coupled in series with the output of op-amp 62.

The amplified signal representing current output by op-amp 62 and fed through resistor R15 is connected to the current A/D conversion circuit 36 through an isolated amplifier circuit 64. Advantageously, this may isolate one side of the circuit from the other and prevent ground loops, which could cause total destruction in the data collected. Furthermore, this may also isolate transients from the current ND conversion circuit 36 to prevent damage to the current ND conversion circuit 36 and/or the controller 44 in the event thereof. In one exemplary implementation, a photoconductive coupling scheme may be used, e.g., using the optocoupler 66, which may be a LOC110 linear optocoupler available from Clare, Inc. or other suitable device. Other isolation amplifier circuits may be used in the alternative.

Normally an optocoupler, such as the LOC110, generates a non linear output because it uses an LED with nonlinear time and temperature characteristics. However, to simplify the meter design, a linear amplification may be desired. As such, by connecting optocoupler 66 in series between two op-amp circuits, a linear output signal may be generated. On the load side (e.g., between the amplifier circuit 60 and the optocoupler 66), the positive input of an op-amp 68 may be coupled to resister R15 from amplifier circuit 60, with the negative input coupled to pin 4 of the LOC110 linear optocoupler 66. A resistor R16 further couples the negative input of the op-amp 68 and pin 4 of the LOC110 linear optocoupler 66 to ground. The output of op-amp 68 is coupled to pin 2 of the LOC110 linear optocoupler 66 through a resistor R17, with feedback from the output to the negative input of op-amp 68 made through a capacitor C1.

On the converter side (e.g., between the optocoupler 66 and the current ND conversion circuit 36), the positive input of an op-amp 70 is coupled to pin 5 of the LOC110 linear optocoupler 66. A resistor R18 further couples the positive input of the op-amp 70 and pin 5 of the LOC110 linear optocoupler 66 to ground. A feedback line is coupled between the output and the negative input of op-amp 70, with the output of op-amp 70 coupled to line 30 for output to the current ND conversion circuit 36 (FIG. 1).

Pins 1, 3 and 6 of the LOC110 linear optocoupler 66 are respectively coupled to ground, VCC1 and VCC2. To calculate the desired values for resistors R16 and R18, a few considerations may be taken into account. In particular, the values of R16 and R18 may be determined with respect to the servo gain (K₁), which is a ratio of a servo photocurrent to an LED forward current (I_{F}) for the LOC110 linear optocoupler 66 (which is typically about 0.007 for an LED forward current of 10 mA and a Vcc of 15V), and the forward gain (K₂), which is a ratio of an output photocurrent to I_{F} (which is also typically about 0.007 for an LED forward current of 10 mA and a Vcc of 15V). To determine R16, the product of the servo photocurrent (I₁) and R16 will track the input voltage (V_{IN}). This equation may be rewritten as V_{IN}=(I₁)(R16). However, I₁ is known with respect to K₁, and thus the equation becomes I_{I}=(K₁)(I_{F}). To determine R16, the maximum desired value of I_{F} should be used that would correspond to a maximum desired V_{IN}, which in one embodiment may be 2V. As such, solving the preceding equation for R16 yields R16=(V_{IN})/((K₁)(I_{F})). Using a minimum value of 0.004 for K₁, 2V for V_{IN}, and 15 mA for I_{F} gives a value of about 33.3 kΩ.

To determine R18, the output voltage (V_{OUT}) will follow the product of the output current (I₂) and R18. This equation may be rewritten as V_{OUT}=(I₂)(R18). I₂, similarly to I₁, may be rewritten as I₂=(K₂)(I_{F}). Substituting the preceding equation in to the one preceding that yields R18=(V_{OUT})/((K₂)(I_{F})). As such, and taking the above equations with respect to R16 into account, the ratio of V_{IN} to V_{OUT} may determine what R18 should be. Thus, when V_{OUT} is desired to be twice that of V_{IN}, solving for the preceding equation using a minimum value of 0.004 for K₂, 4V for V_{OUT}, and 15 mA for I_{F} gives a value of about 66.6 kΩ. In alternative embodiments, the equations above, which are also detailed and used in application note AN-107 for the LOC110 linear optocoupler 66, may be used to provide resistive values for R16 and R18 to utilize photoconductive operation for the optocoupler. The other resistance R17 is set in the circuit to keep op-amp 68 from overloading the LOC110 chip, and typically has no effect on the gain. Thus, there is no required value for R17 as long as a sufficiently large resistance is chosen, which may be a resistance of about 300Ω.

To generate the signal representing voltage across the load on line 22, voltmeter 18 is implemented using a voltage divider including resistors R1 and R2, which operates to step down the high voltage. This is typically necessary because the high voltages that are input into the system would in many cases be harmful to most ND converters. The resistance values can be altered to accommodate the step down needed for each specific application of meter 10. In one exemplary embodiment, for example, where a high voltage source of about 30V is used, resistor values for R1 and R2 of about 10 KΩ and about 1 KΩ, respectively, may be used in order to give a factor of ten step down and a voltage of about 3 V for the A/D converter and other circuit elements. In higher voltage applications more likely encountered in vehicle charging stations and other high voltage applications (e.g., 240V, 480V or even higher), a larger R1/R2 ratio may be used to provide a higher step down factor and appropriately scale the voltage to a range suitable for further processing.

In the illustrated embodiment, however, the voltage output on line 22 still may be too high for the optocoupler circuit, and therefore an amplifier circuit 72, including an op-amp 74, may be used to step the voltage down further to about 2V. Therefore, in amplifier circuit 72, the positive input of op-amp 74 is coupled to the output of voltage divider 18 through resistor R22, and coupled to ground through resistor R23. The negative input of op-amp 74 is coupled to resistor R11 of amplifier circuit 60. A feedback loop is coupled between the output and negative input of op-amp 74 through a feedback resistor R24, and an output resistor R25 is coupled in series with the output of op-amp 74.

The amplified signal representing voltage output by op-amp 74 and fed through resistor R25 is connected to the voltage ND converter circuit 38 through an isolation amplifier circuit 76, which is similarly configured to isolation amplifier circuit 64, and which includes an optocoupler 78 such as a LOC110 linear optocoupler, along with op-amps 80, 82 respectively coupled to load and converter sides of optocoupler 78.

Resistors R26-R28 of isolation amplifier circuit 76 are similar to resistors R16-R18 of isolation amplifier circuit 64, as is capacitor C2 to capacitor C1. The output of op-amp 82 is coupled to line 32 for output to the voltage ND conversion circuit 38 (FIG. 1).

It will be appreciated that the components used in step down circuit 24 of FIG. 2 may vary in different embodiments. For example, in one test embodiment, a signal to be measured is drawn from a 30V power supply and is fed into a variable resistance load in order to simulate the changing current drawn by a car battery. FIG. 3, for example, illustrates an exemplary test load design 90 including six sets of power resistors 92 connected in parallel, with each resistor 92 rated at 25 watts, 3 A, and 45V. Such a test load enables the resistance of the load to be adjusted by connecting from point A to any other point along its length. Furthermore, referring to FIG. 2, in the test embodiment, resistor R1 is about 10 KΩ, resistor R2 is about 1 KΩ, resistors R11-R15 and R21-R25 are each about 10 KΩ, resistors R16 and R26 are each about 33 KΩ, resistors R17 and R27 are each about 300Ω and resistors R18 and R28 are each about 66 KΩ. Capacitors C1 and C2 are each about 200 pF. In addition, while various alternate op-amps may be used, op-amps 62, 68, 70, 74, 80 and 82 may be implemented, for example, using LF347 op-amps available from National Semiconductor.

For a vehicle charging station or other similarly high power application, e.g., one having a 480V and 300 A load, the values of the resistors and capacitors utilized in circuit 24 may be appropriately adjusted. In many applications circuit 24 may be adapted for any particular load voltage and current simply by selecting appropriate resistors R1 and R2 and shunt 16 to appropriately scale the voltage and current to which the load is subjected to ranges suitable for processing by the remainder of circuit 24.

Returning to FIG. 1, a number of different types of ND conversion circuits may be used to implement conversion circuits 36, 38. In one implementation, a Personal Daq/3000 series Data Acquisition Module available from IOtech, Inc. may be used for each conversion circuit 36, 38. This IOTech converter has 16-bit resolution and a 1 MHz sampling rate. The IOTech converter also has two modes of operation, single ended and differential and comes with 16 single ended or 8 differential built-in input channels. In single ended mode all input signals are connected to their own channels with a common ground. This mode compares each input to the common ground when reading the data. For the differential mode, which may be used with thermocouples, the positive and negative terminals of the input signal are connected to the high and low connections of the same channel and there is no direct connection to ground. This mode compares the two input signals and eliminates waveforms traveling in the same direction to minimize noise. Single ended mode is used in one embodiment consistent with the invention to measure the current and voltage signals as these signals typically need to be measured separately. It will be appreciated, however, that in other embodiments, particularly in manufactured power meters, other ND conversion circuits, e.g., implemented on semiconductor chips, may be used in the alternative.

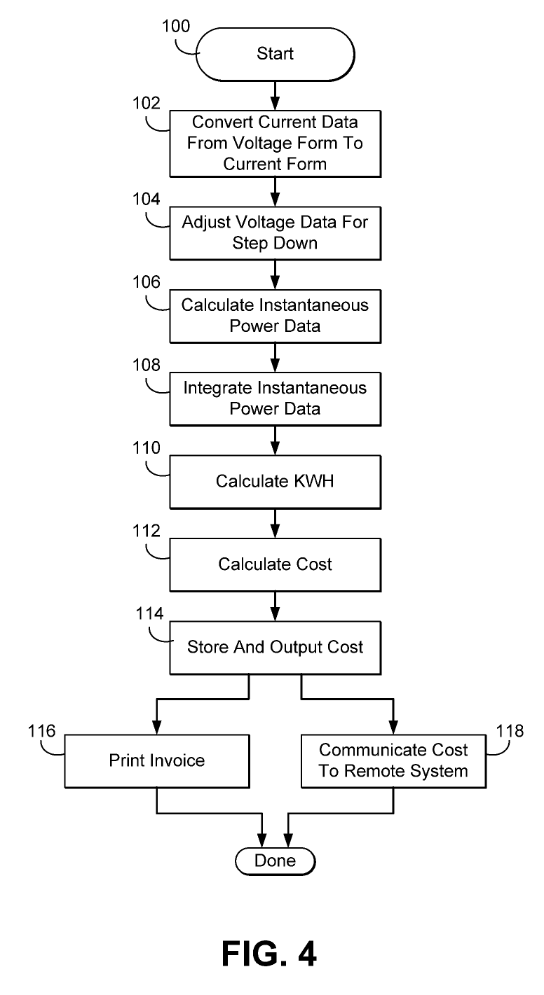

FIG. 4 next illustrates an exemplary routine 100 capable of being executed by program 50 of controller 44, using the current and voltage signals output by A/D conversion circuit 34. The type and language of program 50 will typically depend on what model A/D converter is used for each individual application, as well as other design preferences.

Routine 100 receives as input an array of data points, including both current data points indicative of instantaneous digital current values output by current ND conversion circuit 36 and instantaneous digital voltage values output by voltage A/D conversion circuit 38 at a plurality of sample points separated in time based upon a sample rate (e.g., about 1 MHz). Routine 100 thus begins in block 102 by converting the current data from a voltage form to a current form. For the illustrated test embodiment discussed above, where a nichrome wire with a fixed resistance is used, the conversion may be performed by applying Ohm's law (I=V/R, where R is the known resistance of the nichrome wire, e.g., about 0.054Ω in the illustrated test embodiment). On the other hand, where a shunt element having a fixed scaling factor between current and voltage (e.g., 200 A to 1V) is used, the conversion may be performed by applying the scaling factor associated with the shunt element.

Next, the voltage data is adjusted for the step down in block 104, e.g., based upon the ratio of the resistors in the voltage divider (e.g., by multiplying by 10 in the illustrated test embodiment).

Next, the instantaneous power at each sample point is calculated in block 106, e.g., by multiplying the corresponding current and voltage data points. The instantaneous power data is then integrated in block 108, e.g., using trapezoidal integration, and the result is then converted into KWH in block 110.

In addition, as shown in block 112, meter 10 may also calculate a cost from the calculated KWH power measurement, using a known rate (which may change from day to day), and furthermore, store and output the cost 114, either for display to a customer on a screen, or as shown in blocks 116 and 118, to a printer to print an invoice and/or to a remote system over a network for accounting, billing or other purposes.

While various alternative programs and programming languages may be used to implement routine 100, Table I below illustrates one exemplary implementation in Visual Basic:

TABLE I
Sample Program Code

```
Sub Meter(ByVal Data( ) As Single, ByVal DesiredScans As Long,
ByVal ScanRate As Long)
‘This program is designed to read in the current and voltage ‘signals,
adjust them back to their original values, perform ‘trapezoidal integration,
and print an invoice to the screen.
    Dim current(DesiredScans) As Single
    Dim voltage(DesiredScans) As Single
    Dim power(DesiredScans) As Single
    Dim kwh As Single
    Dim resist As Single = 0.054
    Dim Price As Double
    Dim Rate As Double = 0.27
    Dim h As Double = ScanRate  ‘ScanRate is in Hz
    Dim n As integer = DesiredScans
    ‘putting data in two arrays
    Dim p As Integer = 0
    For p = 0 To n − 1 Step 2
        current(p) = Data(p)
        voltage(p) = Data(p + 1)
    Next
    ‘converting the current reading from voltage form to current form
    Dim q As Integer = 0
    For q = 0 To n − 1
        current(q) = current(q)/resist
    Next
    ‘Adjusting voltage because of step down
    Dim m As Integer = 0
    For m = 0 To n − 1
        voltage(m) = voltage(m) * 10
    Next
    ‘calculating power by multiplying current and voltage
    Dim j As Integer = 0
    For j = 0 To n − 1
        power(j) = voltage(j) * current(j)
    Next
‘perform trapezoidal integration
    kwh = 0.5 * power(0)
    Dim k As Integer = 0
    For k = 1 To n − 2
        kwh = kwh + power(k)
    Next
    kwh = (kwh + 0.5 * power(n − 1)) / (1000*h)
    kwh = kwh / 3600
    ‘to convert from kw/sec to kwh
    Price = kwh * Rate
    MsgBox(kwh & “ KWH were used.” &  “ The rate was $” &
Rate & “,  and $” & Price & “ is the
    amount owed.”)
  End Sub
```

Embodiments of the invention therefore are capable of providing a relatively inexpensive high power DC meter for use as a metering system for an electric vehicle recharging station, among other applications. The system can easily be modified to fit a wide range of input voltages and currents, as well as a variety of applications. For example, by replacing the resisters used in the voltage divider 18, and the shunt resistor 16, and in some instances adjusting the gain of amplifier circuits 62, 74 (FIG. 2), the entire system can be adjusted to handle a wide variety of specific input conditions. Advantageously, because of the design thereof, the meter preserves the linearity of signals therein. The linearity of the transition from a high voltage signal or a high current signal to a respective lower voltage signal or a lower current signal is advantageous, as it results in accurate measurements and easily allows the lower voltage signal or lower current signal to be scaled back for accurate values representative of the respective high voltage signal and high current signal.

The routines executed to implement the embodiments of the invention, whether implemented as part of an operating system or a specific application, component, program, object, module or sequence of instructions executed by one or more controllers 44 will be referred to herein as a “sequence of operations,” a “program product,” or, more simply, “program code.” The program code typically comprises one or more instructions that are resident at various times in various memory (such as memory 48) and storage devices in a controller 44, and that, when read and executed by one or more CPUs 46 of the controller 44 cause that CPU 46 to perform the steps necessary to execute steps, elements, and/or blocks embodying the various aspects of the invention.

Moreover, while the invention has been described in the context of fully functioning controllers 44 and computing systems, those skilled in the art will appreciate that the various embodiments of the invention are capable of being distributed as a program product in a variety of forms, and that the invention applies equally regardless of the particular type of computer readable signal bearing media used to actually carry out the distribution. Examples of computer readable signal bearing media include but are not limited to physical, tangible, and non-transitory recordable type media such as volatile and nonvolatile memory devices, floppy and other removable disks, hard disk drives, USB drives, optical disks (e.g., CD-ROM's, DVD's, Blu-Ray discs, etc.), among others.

In addition, various program code described herein may be identified based upon the application or software component within which it is implemented in a specific embodiment of the invention. However, it should be appreciated that any particular program nomenclature is used merely for convenience, and thus the invention should not be limited to use solely in any specific application identified and/or implied by such nomenclature. Furthermore, given the typically endless number of manners in which computer programs may be organized into routines, procedures, methods, modules, objects, and the like, as well as the various manners in which program functionality may be allocated among various software layers that are resident within a typical computer (e.g., operating systems, libraries, APIs, applications, applets, etc.), it should be appreciated that the invention is not limited to the specific organization and allocation of program functionality described herein.

While this invention has been illustrated by a description of various preferred embodiments and while these embodiments have been described in considerable detail in order to describe the best mode of practicing the invention, it is not the intention of the inventor to restrict or in any way limit the scope of the appended claims to such detail. Additional advantages and modifications within the spirit and scope of the invention will readily appear to those skilled in the art. For example, the controller 44 may include more or fewer components than those illustrated and described. Furthermore, a person having ordinary skill in the art will appreciate that embodiments of the invention may be used with high voltage DC sources that have output higher or lower DC voltage and current than those disclosed herein without departing from the scope of the invention. As such, alternative embodiments of the invention may include alternative resistor and capacitor values than those disclosed herein without departing from the scope of the invention. Moreover, a person having ordinary skill in the art will appreciate that any of the blocks of the above flowchart may be deleted, augmented, made to be simultaneous with another, combined, or be otherwise altered in accordance with the principles of the embodiments of the invention. Accordingly, departures may be made from such details without departing from the spirit or scope of applicant's general inventive concept. Therefore, the invention lies in the claims hereinafter appended.

What is claimed is:

1. A high voltage and high current direct current (DC) power meter, comprising:
a current step down circuit configured to sense a current applied to a load by a power source, the current step down circuit including a shunt element coupled in series with the load and configured to generate a first analog signal having a voltage representative of current through the load;
a voltage step down circuit configured to sense a voltage across the load, the voltage step down circuit including a voltage divider coupled in parallel with the load and configured to generate a second analog signal having a voltage representative of voltage across the load;
a first isolation amplifier circuit including a first optocoupler and configured to generate from the first analog signal a first isolated analog signal having a voltage representative of the current through the load;
a second isolation amplifier circuit including a second optocoupler and configured to generate from the second analog signal a second isolated analog signal having a voltage representative of the voltage across the load;
an analog to digital conversion circuit isolated from the current and voltage step down circuits by the first and second isolation amplifier circuits and configured to respectively generate from the first and second isolated analog signals first and second digital signals respectively representative of the current through the load and the voltage across the load; and
a controller coupled to the analog to digital conversion circuit and configured to calculate consumed energy for the load by calculating instantaneous power consumed by the load at a plurality of sample points using the first and second digital signals and integrating the instantaneous power over time.

2. The high voltage and high current DC power meter of claim 1, wherein the controller is further configured to calculate a cost using the calculated consumed energy and a rate.

3. The high voltage and high current DC power meter of claim 1, wherein the current and voltage step down circuits each further include an amplifier circuit comprising an op-amp.

4. The high voltage and high current DC power meter of claim 1, wherein the first and second isolation amplifier circuits each include first and second op-amps coupled to inputs and outputs of the respective first and second optocouplers to configure the first and second optocouplers to output linear signals in a photoconductive coupling mode.

5. A charging station for an electric vehicle comprising the high voltage and high current DC power meter of claim 1.

6. A method of assembling a high voltage and high current direct current (DC) power meter, comprising:
configuring a current step down circuit that includes a shunt element adaptable to couple in series with a load and configured to generate a first analog signal having a voltage representative of a current through the load;
configuring a voltage step down circuit that includes a voltage divider adaptable to couple in parallel with the load and configured to generate a second analog signal having a voltage representative of a voltage across the load;
coupling a first isolation amplifier circuit that includes a first optocoupler to the first analog signal to generate a first isolated analog signal having a voltage representative of the current through the load;
coupling a second isolation amplifier circuit that includes a second optocoupler to the second analog signal to generate a second isolated analog signal having a voltage representative of the voltage through the load.

7. The method of claim 6, further comprising:
coupling a first analog-to-digital (A/D) converter to the first isolated analog signal to generate a first digital signal that includes first data indicating the current through the load; and
coupling a second ND converter to the second isolated analog signal to generate a second digital signal that includes second data indicating the current through the load.

8. The method of claim 7, further comprising:
coupling a controller to the first ND converter and the second A/D converter to calculate consumed energy for the load by calculating instantaneous power consumed by the load at a plurality of sample points using the first and second data and integrating the instantaneous power over time.

9. A method of calculating power consumed by a load, comprising:
coupling at least a portion of a current step down circuit in series with a load;
generating a first analog signal that is representative of a current through the load with the current step down circuit;
coupling at least a portion of a voltage step down circuit in parallel with the load;
generating a second analog signal that is representative of a voltage across the load with the voltage step down circuit;
optoelectrically isolating the first analog signal to generate a first isolated analog signal;
optoelectrically isolating the second analog signal to generate a second isolated analog signal;
converting the first and second isolated analog signals into respective first and second digital signals; and
calculating power consumed by the load based upon the first and second digital signals.

10. The method of claim 9, wherein coupling the at least a portion of the current step down circuit in series with the load includes coupling a shunt element of the current step down circuit in series with the load.

11. The method of claim 9, wherein coupling the at least a portion of the voltage step down circuit in parallel with the load includes coupling a voltage divider of the voltage step down circuit in parallel with the load.

12. The method of claim 9, wherein calculating the power consumed by the load further comprises:
storing the first digital signal in a first array; and
storing the second digital signal in a second array.

13. The method of claim 9, further comprising:
converting the first digital signal which is representative of the current through the load with the current step down circuit into an actual value of current through the load by dividing the first digital signal by a resistance value associated with the load.

14. The method of claim 13, further comprising:
converting the second digital signal which is representative of the voltage across the load with the voltage step down circuit into a normalized voltage by multiplying the second digital signal by a predetermined value.

15. The method of claim 14, wherein calculating the power consumed by the load includes:
multiplying the actual value of the current through the load by the normalized voltage.

16. The method of claim 9, wherein calculating the power consumed by the load includes:
calculating a plurality of data points representative of the power consumed by the load over a corresponding plurality of time points.

17. The method of claim 16, further comprising:
performing a trapezoidal integration of the plurality of data points over the plurality of time points to determine kilowatt hours of power consumed.

18. The method of claim 17, further comprising:
indicating a cost associated with the kilowatt hours of power consumed.
